(19) United States
(12) Patent Application Publication
(10) Pub. No.: US 2026/0121134 A1
(43) Pub. Date: Apr. 30, 2026

(54) BATTERY MANAGEMENT SYSTEM

(71) Applicant: TOYOTA JIDOSHA KABUSHIKI KAISHA, Toyota-shi (JP)

(72) Inventor: Takeaki SUZUKI, Nagoya-shi (JP)

(73) Assignee: TOYOTA JIDOSHA KABUSHIKI KAISHA, Toyota-shi (JP)

(21) Appl. No.: 19/009,078

(22) Filed: Jan. 3, 2025

(30) Foreign Application Priority Data
Mar. 25, 2024 (JP) 2024-047676

(51) Int. Cl. H01M 10/42; G01R 31/392; H01M 10/48

(52) U.S. Cl. CPC H01M 10/425; H01M 10/48; G01R 31/392; H01M 2010/4271; H01M 2010/4278; H01M 2220/20

(57) ABSTRACT

A battery management system for managing a battery, including: a notification device that notifies price-related information regarding a trade-in price of a battery based on a state of the battery. Accordingly, the user can recognize the price-related information of the battery. The user who recognizes the price-related information of the battery can examine the replacement time of the battery after grasping the price-related information. As a result, it is possible to improve convenience when the user considers the replacement time of the battery.

### CROSS-REFERENCE TO RELATED APPLICATION

This application claims priority to Japanese Patent Application No. 2024-047676 filed on Mar. 25, 2024, incorporated herein by reference in its entirety.

### BACKGROUND

### 1. Technical Field

The present disclosure relates to a battery management system.

### 2. Description of Related Art

Hitherto, as a battery management system of this type, a battery management system that manages a battery (assembled battery) has been proposed (see, for example, Japanese Unexamined Patent Application Publication No. 2021-40370 (JP 2021-40370 A)). In this system, a notification is issued about the deterioration degree of the battery.

### SUMMARY

In recent years, it has been proposed to collect a used battery as a trade-in and reuse it when the battery is replaced. In the reuse of a battery, a trade-in price is an important factor when a user considers the replacement timing of the battery. In the above battery management system, a notification is issued about the deterioration degree of the battery, but cannot be issued about the trade-in price of the battery. Therefore, convenience when the user considers the replacement timing of the battery decreases.

A main object of the battery management system of the present disclosure is to improve convenience when a user considers a replacement timing of a battery.

The battery management system of the present disclosure adopts the following measures in order to achieve the above main object.

The battery management system of the present disclosure is a battery management system configured to manage a battery. The battery management system includes a notification device configured to issue a notification about price-related information on a trade-in price of the battery based on a state of the battery.

The battery management system of the present disclosure includes the notification device configured to issue the notification about the price-related information on the trade-in price of the battery based on the state of the battery. Accordingly, the user can recognize the price-related information of the battery. The user who recognizes the price-related information of the battery can consider the replacement timing of the battery while grasping the price-related information. As a result, it is possible to improve convenience when the user considers the replacement timing of the battery.

In the battery management system of the present disclosure, a deterioration degree of the battery may be calculated as the state of the battery. In this way, the user can recognize the price-related information based on the deterioration degree of the battery.

In this case,

The notification device may be configured to issue the notification about the price-related information when the deterioration degree is lower than a reference value of the deterioration degree of the battery in a device in which the battery is to be reused.

In this way, the notification about the price-related information of the battery can be issued before the deterioration degree is higher than the reference value in the device in which the battery is to be reused. Accordingly, the user can be notified about the price-related information at a more appropriate timing.

In the battery management system of the present disclosure, the battery may be mounted on a vehicle, and the notification device may be a display device that is mounted on the vehicle or a mobile terminal and is configured to display the price-related information.

In this way, the user in the vehicle or the user with the mobile terminal can recognize the price-related information. Accordingly, it is possible to improve convenience when the user considers the replacement timing of the battery.

The battery management system of the present disclosure may include an information processing device in which an application for executing processing using the price-related information is installed.

In this way, the processing using the price-related information can be executed in the application. Therefore, the user's convenience can further be improved.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a configuration diagram illustrating an outline of a configuration of a battery management system 10 according to the present embodiment;

FIG. 2 is a flow chart illustrating an exemplary display control routine executed by ECU 70 of battery electric vehicle 20;

FIG. 3 is an explanatory diagram for explaining an exemplary relation between the pick-up price P of the stationary storage battery and tu of elapsed times after battery electric vehicle 20 is shipped from the manufacturer of the stationary storage battery when the health level SOH and the replaced battery 36 are reused as the stationary storage battery;

FIG. 4 is an explanatory diagram illustrating an example of the display of the display device 50 that has received the display command;

FIG. 5 is an explanatory diagram illustrating an exemplary display of the mobile terminal 80 that has received the display command; and

FIG. 6 is an explanatory diagram illustrating an example of the display of the navigation device 52 that has received the display command.

### DETAILED DESCRIPTION OF EMBODIMENTS

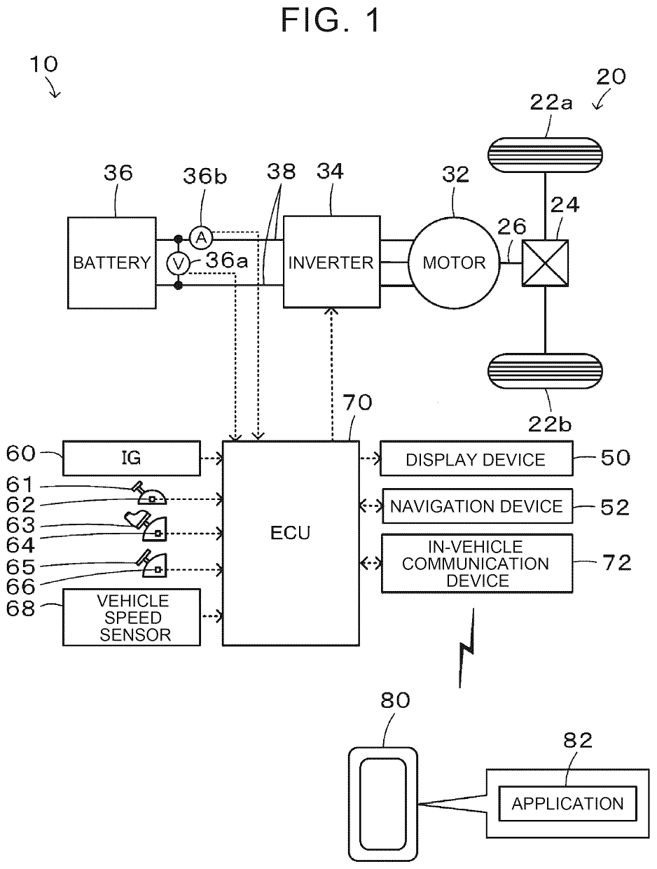

Embodiments of the present disclosure will be described with reference to the drawings. FIG. 1 is a configuration diagram schematically showing a configuration of a battery management system 10 according to the present embodiment. The battery management system 10 according to the embodiment includes a battery electric vehicle 20 and a mobile terminal 80.

As illustrated, battery electric vehicle 20 includes a motor 32, an inverter 34, a battery 36, a display device 50, a navigation device 52, and an electronic control unit (hereinafter referred to as “ECU”) 70.

The motor 32 is configured as a synchronous generator-motor, and includes a rotor in which permanent magnets are embedded and a stator on which three-phase coils are wound. The rotor of the motor 32 is connected to a drive shaft 26 connected to the drive wheel 22a, 22b via a differential gear 24.

Inverter 34 is connected to motor 32 and to power line 38. The inverter 34 is configured as a known inverter circuit including six transistors and six diodes.

The battery 36 is configured as, for example, a lithium-ion secondary battery or a nickel-hydrogen secondary battery, and is exchangeably connected to the power line 38.

The display device 50 is installed in the passenger compartment, and is configured as a display that visually displays a power meter 50a indicating the output of the motor 32, a speedometer 50b indicating the vehicle speed V, and the like.

The navigation device 52 includes a main body having a built-in control unit, a GPS antenna, and a display. The control unit of the main body includes a storage medium (for example, a hard disk or an SSD), an input/output port, and a communication port. The storage medium stores map information and the like. The map information includes service information (for example, tourist information, a parking lot, and the like), road information in each traveling section (for example, between traffic lights and intersections), and the like. The road information includes distance information, width information, lane number information, area information (urban area or suburban area), type information (general road or expressway), gradient information, statutory speed, number of traffic lights, and the like. GPS of the antennae receives information about the current location of the own vehicle. The display is configured as a touch panel type display, and displays various kinds of information such as map information, information on a current location of the own vehicle, and information on a traveling route to a destination, and the like, and allows a user to input various kinds of instructions. When a display is operated by a user to set a destination, a main body of a navigation device 52 sets a scheduled travel route from a current position of a vehicle to a destination based on map information, a current position of the vehicle, and a destination, and displays the set scheduled travel route on a display to guide a route

ECU 70 is configured as a microprocessor centered on a CPU (not shown), and includes, in addition to a CPU, a ROM for storing a process program, a RAM for temporarily storing data, an input/output port, a communication port (neither of which is shown), and the like.

ECU 70 receives input signals from various sensors through the input ports. Examples of the signal inputted to ECU 70 include a rotational position Om from a rotational position detection sensor (for example, a resolver) that detects the rotational position of the rotor of the motor 32, a battery voltage Vb from a voltage sensor 36a that detects the voltage between terminals of the battery 36, and a current Ib from a current sensor 36b that detects the charge/discharge current of the battery 36. ECU 70 also receives information required for the travel control. Examples of the information necessary for the travel control include an ignition signal from the ignition switch 60, a shift position from the shift position sensor 62 for detecting the operation position of the shift lever 61, an accelerator operation amount from the accelerator pedal position sensor 64 for detecting the depression amount of the accelerator pedal 63, a brake pedal position from the brake pedal position sensor 66 for detecting the depression amount of the brake pedal 65, and a vehicle speed V from the vehicle speed sensor 68.

Various control signals are output from ECU 70 via an output port. Examples of the signal outputted from ECU 70 include a switching control signal to the transistor of the inverter 34 and an image signal to the display device 50.

ECU 70 wirelessly transmits and receives various types of data to and from the mobile terminal 80 via an in-vehicle communication device (for example, a DCM (data communication module)) 72.

ECU 70 calculates the power storage ratio SOC of the battery 36 based on the integrated value of the current Ib of the battery 36 from the current sensor 36b and the battery voltage Vb of the battery 36 from the voltage sensor 36a when no current flows. The power storage ratio SOC is a ratio of the amount of electric power that can be discharged from the battery 36 to the total capacity of the battery 36. ECU 70 calculates the health level SOH of the battery 36 from the integrated value of the current Ib of the battery 36 from the current sensor 36b. The health level SOH is an inverse of the deterioration degree SOD indicating the degree of deterioration of the battery 36, and is calculated as a value obtained by multiplying the inverse of the integrated value ΣIb of the current Ib of the battery 36 from the start of use after shipment of the battery electric vehicle 20 up to now by the conversion factor K (positive value).

In battery electric vehicle 20, the inverter 34 is controlled by ECU 70 so as to travel with power from the motor 32.

The mobile terminal 80 is configured as a smartphone, a tablet terminal, or the like as an information processing device. The mobile terminal 80 is carried by the driver of battery electric vehicle 20 and exchanges various types of data with battery electric vehicle 20 by radio communication. An application for displaying the status of battery electric vehicle 20 is installed in the mobile terminal 80.

In the battery management system 10, the state of the battery 36 is managed, and battery information related to the battery 36 is displayed on the display of the display device 50 or the navigation device 52. In addition, ECU 70 of battery electric vehicle 20 transmits the battery data to the mobile terminal 80. Upon receiving the battery information, the mobile terminal 80 executes processing using the information received by the application.

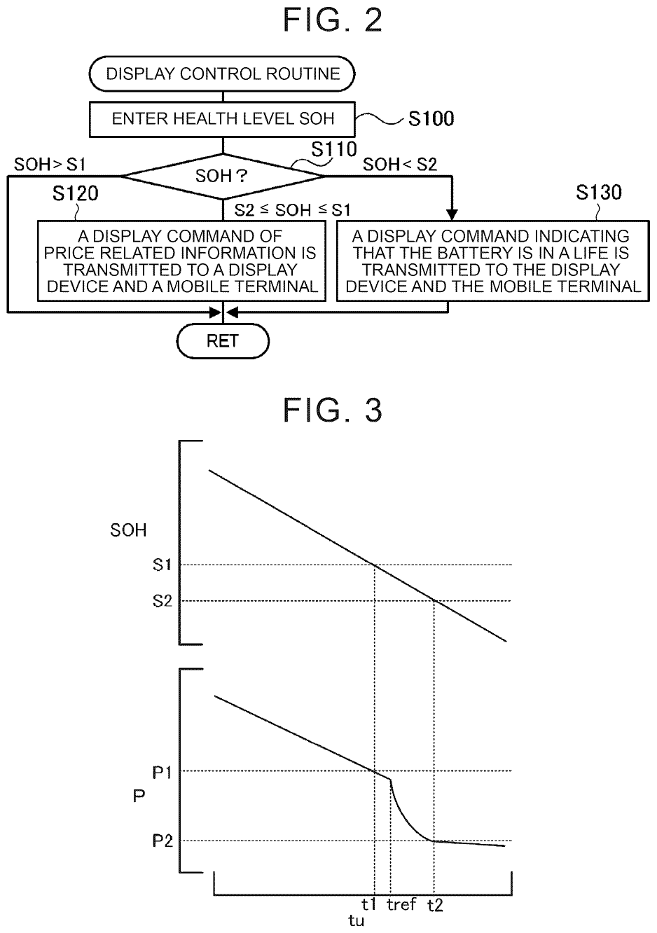

Next, the operation of the battery management system 10 configured as described above, in particular, the operation when the price related information regarding the trade-in price P of the battery 36 is displayed will be described. FIG. 2 is a flow chart illustrating an exemplary display control routine executed by ECU 70 of battery electric vehicle 20. This routine is executed when the display update condition is satisfied. The display-updating condition is executed when any one of the first condition when battery electric vehicle 20 system is started, the second condition when the system is stopped, the third condition when the periodic inspection is performed, and the fourth condition when the predetermined period (for example, half a year or one year) has elapsed is satisfied.

When this routine is executed, CPU of ECU 70 executes a process of inputting the health level SOH of the battery 36 (S100). The health level SOH receives a value set from the integrated value ΣIb of the current Ib of the battery 36 from the current sensor 36b.

Subsequently, the health level SOH is compared with the threshold (reference value) S1 and the threshold S2 (S110). Here, the thresholds S1, S2 will be described. FIG. 3 is an explanatory diagram for explaining an exemplary relation between the pick-up price P of the stationary storage battery and tu of elapsed times after battery electric vehicle 20 is shipped from the manufacturer of the stationary storage battery when the health level SOH and the replaced battery 36 are reused as the stationary storage battery. As the elapsed time tu elapses, the health level SOH of the battery 36 decreases (deteriorates). As shown in the figure, the trade-in price P decreases with the elapse of the elapsed time tu, rapidly decreases after the elapse of the time tref (e.g., 3 years, 4 years, 5 years, etc.), and then gradually decreases in the low price range after the elapse of the time t2. If the user desires a relatively higher trade-in price P, it may be desirable to replace the battery 36 prior to the expiration of the time tref. The threshold S1 is set to a health level SOH at a time t1 slightly earlier than the time tref (for example, one month before the time tref, two months before, three months before, and the like). The threshold S2 is set to the health level SOH at the time t2. That is, the threshold S1 is a threshold for determining whether or not to recommend replacement of the battery 36 from the viewpoint of the trade-in price P of the battery 36. If the user wishes to use the battery 36 from the withdrawal price P to the end of life, it is desirable to replace the battery 36 by t2 of time. The threshold S2 is a threshold for determining whether or not to recommend replacement of the battery 36 from the viewpoint of the life of the battery 36.

In S110, when the health level SOH is higher than the threshold S1, it is determined that the health level SOH of the battery 36 is high and replacement is not required to be recommended, and the routine is ended.

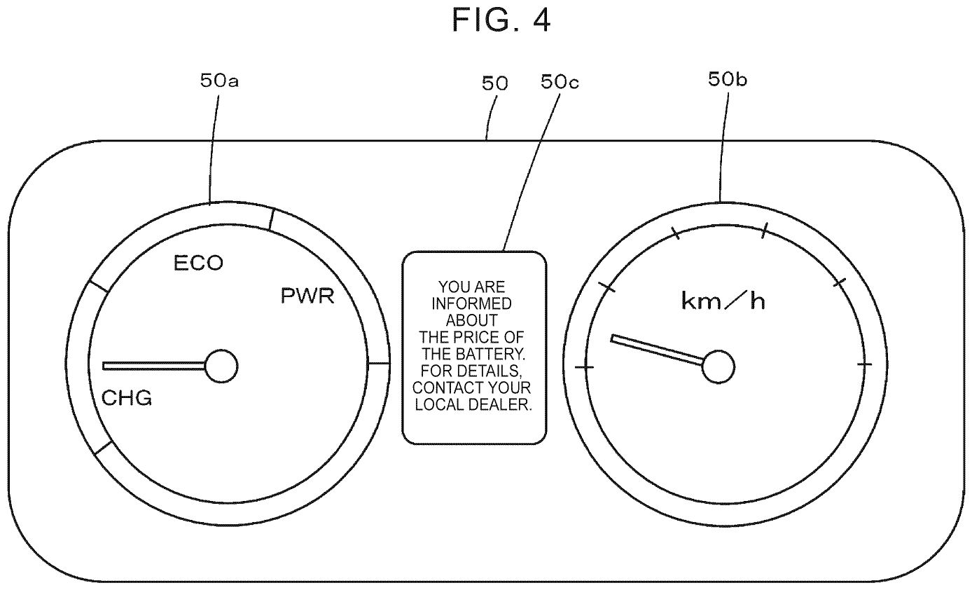

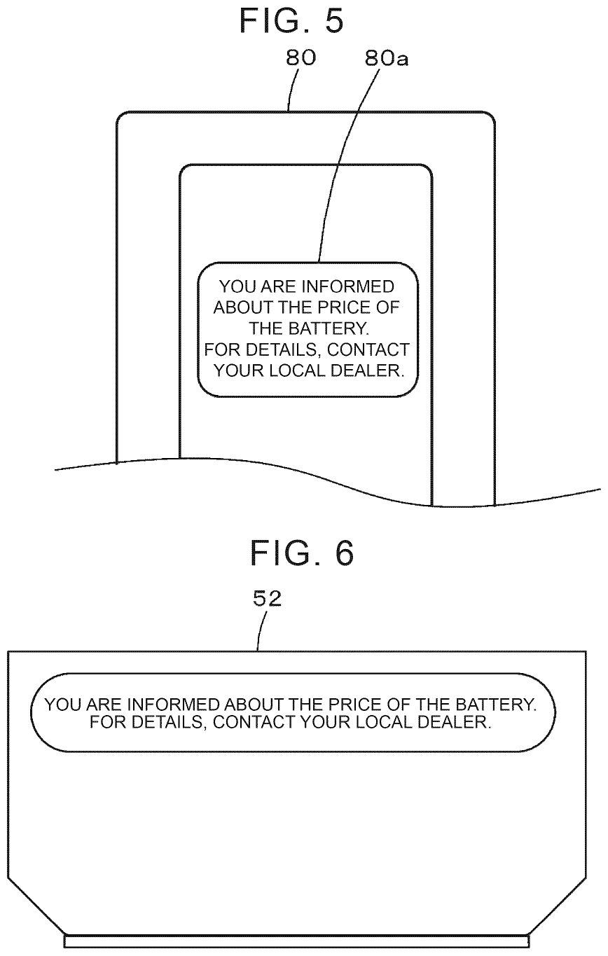

In S110, when the health level SOH is equal to or higher than the threshold S2 and equal to or lower than the threshold S1, it is determined that the time when the replacement of the battery 36 is recommended from the viewpoint of the trade-in price P, and information indicating that there is an announcement regarding the trade-in price P of the battery 36 as the price related information related to the trade-in price P is transmitted to the display device 50 and the mobile terminal 80 (S120), and the routine is ended. FIG. 4 is an explanatory diagram illustrating an example of the display of the display device 50 that has received the display command. FIG. 5 is an explanatory diagram illustrating an example of the display of the mobile terminal 80 that has received the display command. As illustrated in FIG. 4, the display device 50 displays the power meter 50a and the speedometer 50b. When receiving the indication command, the display device 50 has a notice regarding the price P of the battery to be taken in as price-related information between the power meter 50a and the speedometer 50b. For details, please contact the sales point. “Displays the sentence 50c. Such a display allows the user in the passenger compartment to recognize the price-related information of the battery 36. The mobile terminal 80 that has received the display command has been notified by the application about the price P of the battery as price related information as shown in FIG. 5. For details, please contact the sales point.” Displays the sentence 80a. Such a display allows the user carrying the mobile terminal 80 to recognize the price-related information of the battery 36. The user who has recognized the price-related information of the battery 36 by at least one of the display on the display device 50 and the display on the mobile terminal 80 can consider the replacement time of the battery 36 after recognizing the specific trade-in price P of the battery 36 by inquiring the sales point. As described above, since the user can consider the replacement time of the battery 36 after grasping the price-related information, it is possible to improve convenience when the user considers the replacement time of the battery 36.

When the health level SOH is less than the threshold S2 in S110, a display command indicating that the battery 36 is in the life is transmitted to the display device 50 and the mobile terminal 80 (S130), and the routine ends. The display device 50 and the mobile terminal 80 that have received the display command indicating that the battery 36 is in the end of its service life are “the battery 36 is in the end of its service life”. Replacement is recommended. “An indication that the battery 36, such as a battery, is in the end of its life is given. As a result, the user in the passenger compartment or the user carrying the mobile terminal 80 can recognize that the battery 36 has reached the end of its life. Since the user can consider the replacement time of the battery 36 after knowing that the battery 36 has reached the end of its life, it is possible to improve convenience when the user considers the replacement time of the battery 36.

According to the battery management system 10 of the present embodiment described above, by displaying the price-related information regarding the trade-in price P of the battery 36 on the display device 50 and the mobile terminal 80 based on the state of the battery 36, it is possible to improve convenience when the user considers the replacement time of the battery 36.

Further, the battery 36 is mounted on battery electric vehicle 20, and the display device 50 is mounted on battery electric vehicle 20, so that the user can improve convenience when considering the replacement time of the battery 36 by displaying the price-related information.

Further, since the mobile terminal 80 is provided with an application that executes processing using price-related information, it is possible to further improve the convenience of the user.

In the embodiments described above, S110 compares the health level SOH with the thresholds S1, S2. However, in S110, the deterioration degree SOD of the battery 36 may be compared with the thresholds S3, S4 instead of the health level SOH. The threshold S3 is a threshold of the deterioration degree of the battery 36 for determining whether or not to recommend replacement of the battery 36 from the viewpoint of the trade-in price P. The threshold S4 is greater than the threshold S3, and is a threshold of the deterioration degree of the battery 36 for determining whether or not to recommend replacement of the battery 36 from the viewpoint of the life of the battery 36. When the deterioration degree SOD is smaller than the threshold S3 in S110, the routine is ended. When the deterioration degree SOD is equal to or greater than the threshold S3 and equal to or less than the threshold S4 in S110, the process proceeds to S120, where a command for displaying price-related information related to the trade-in price P is transmitted to the display device 50 and the mobile terminal 80, and the routine ends. Further, when the deterioration degree SOD is greater than the threshold S4 in S110, the process proceeds to S130, and a display command indicating that the battery 36 is in the life is transmitted to the display device 50 and the mobile terminal 80, and the routine is ended. In addition, in S110, the usage history Hu of the battery 36 may be used instead of the health level SOH and the deterioration degree SOD. In the usage history Hu of the battery 36, the deterioration degree SOD of the battery 36 is higher (the health level SOH is lowered) than when battery electric vehicle 20 is used long and short. Therefore, in S110, when the usage history Hu is less than the threshold H1, the routine ends. Further, in S110, when the usage history Hu is equal to or larger than the threshold H1 and equal to or smaller than the threshold H2 larger than the threshold H1, the process proceeds to S120, and the display command of the price-related information related to the trade-in price P is transmitted to the display device 50 and the mobile terminal 80, and the routine is ended. As the usage history Hu, it is possible to use the total travel distance and usage time since the use after the shipping of battery electric vehicle 20 is started, the number of times of reuse (the number of times of replacement) of the battery 36, the sales history of battery electric vehicle 20 (the number of times sold as a used vehicle), and the like.

In the above-described embodiment, a display command of information indicating that there is a notification regarding the trade-in price P of the battery 36 as the price-related information related to the trade-in price P is transmitted to the display device 50 and the mobile terminal 80 in S120. However, in S120, as the price-related information, the trade-in price P of the battery 36, the price of the battery 36 when battery electric vehicle 20 is purchased, or the ratio of the trade-in price O to the estimated value of the price may be used.

In the above-described embodiment, the display instruction of the price-related information and the information indicating that the battery 36 has reached the end of its life is transmitted to the display device 50 and the mobile terminal 80, and the price-related information and the information indicating that the battery 36 has reached the end of its life are displayed on the display device 50 and the mobile terminal 80. However, a display command of the price-related information and the information indicating that the battery 36 has reached the end of its life may be transmitted to at least one of the display device 50, the mobile terminal 80, and the navigation device 52 to display the price-related information and the information indicating that the battery 36 has reached the end of its life on at least one of the display device 50, the mobile terminal 80, and the navigation device 52. For example, the display instruction of the price-related information and the information indicating that the battery 36 has reached the end of its life may be transmitted only to the navigation device 52. FIG. 6 is an explanatory diagram illustrating an example of the display of the navigation device 52 that has received the display command of the price-related information. As described above, even when displayed on the navigation device 52, it is possible to improve convenience when the user considers the replacement time of the battery 36.

In the above-described embodiment, the threshold S1, S2 is set based on an exemplary relation between the pick-up price P by the manufacturer of the stationary storage battery when the health level SOH and the replaced battery 36 are reused as the stationary storage battery, and tu of elapsed times after the use is started after battery electric vehicle 20 is shipped. However, it may be set based on the relation between the trade-in price P and the travel distance Lr since the use is started after battery electric vehicle 20 is shipped. Here, the relationship between the health level SOH and the trade-in price P and the travel distance Lr is the same as the relationship between the health level SOH and the trade-in price P and the elapsed time tu. That is, the health level SOH decreases when the travel distance Lr is long as compared with when the travel distance is short, and the trade-in price P decreases when the travel distance Lr is long as compared with when the travel distance is short, and decreases rapidly when the travel distance exceeds the predetermined distance L1, and then decreases gradually in the low-price range when the travel distance exceeds the predetermined distance L2 longer than the predetermined distance L1.

In the above-described embodiment, the price-related information and the information indicating that the battery 36 has reached the end of its life are displayed on the display device 50 or the mobile terminal 80. However, the user may be notified of the price-related information and information indicating that the battery 36 has reached the end of its life by outputting a sound, turning on a warning light, or the like.

In the above-described embodiment, the battery management system 10 includes a battery electric vehicle 20 and a mobile terminal 80. However, the battery management system 10 may not include the mobile terminal 80 but may include battery electric vehicle 20.

The correspondence between the main elements of the embodiments and the main elements of the disclosure described in the column of the means for solving the problem will be described. In the embodiment, the battery 36 corresponds to a “battery”, and the display device 30 corresponds to a “notification device”.

Note that the correspondence between the main elements of the embodiment and the main elements of the disclosure described in the section of the means for solving the problem is an example for specifically explaining the embodiment of the disclosure described in the section of the means for solving the problem, and therefore the elements of the disclosure described in the section of the means for solving the problem are not limited. That is, the interpretation of the disclosure described in the section of the means for solving the problem should be performed based on the description in the section, and the embodiments are only specific examples of the disclosure described in the section of the means for solving the problem.

Although the embodiments for carrying out the present disclosure have been described above, the present disclosure is not limited to such embodiments at all, and it is needless to say that the present disclosure can be carried out in various forms without departing from the gist of the present disclosure.

The present disclosure is applicable to a manufacturing industry of a battery management system and the like.

What is claimed is:

1. A battery management system configured to manage a battery, the battery management system comprising a notification device configured to issue a notification about price-related information on a trade-in price of the battery based on a state of the battery.

2. The battery management system according to claim 1, wherein a deterioration degree of the battery is calculated as the state of the battery.

3. The battery management system according to claim 2, wherein the notification device is configured to issue the notification about the price-related information when the deterioration degree is lower than a reference value of the deterioration degree of the battery in a device in which the battery is to be reused.

4. The battery management system according to claim 1, wherein:
the battery is mounted on a vehicle; and
the notification device is a display device that is mounted on the vehicle or a mobile terminal and is configured to display the price-related information.

5. The battery management system according to claim 1, further comprising an information processing device in which an application for executing processing using the price-related information is installed.
